(19) United States
(12) Patent Application Publication
(10) Pub. No.: US 2025/0015095 A1
(43) Pub. Date: Jan. 9, 2025

(54) ELECTRONIC DEVICE

(71) Applicant: InnoLux Corporation, Miao-Li County (TW)

(72) Inventors: Cheng-Shen PAN, Miao-Li County (TW); Cheng-Min WU, Miao-Li County (TW); Chien-Feng SHIH, Miao-Li County (TW); Ming-Jhih CHEN, Miao-Li County (TW); Cing-Hong CHEN, Miao-Li County (TW); Wei-Fan TENG, Miao-Li County (TW)

(21) Appl. No.: 18/734,078

(22) Filed: Jun. 5, 2024

(30) Foreign Application Priority Data
Jul. 6, 2023 (CN) 202310823958.X

(51) Int. Cl. H01L 27/12

(52) U.S. Cl. CPC H01L 27/124

(57) ABSTRACT

Electronic devices are provided. The electronic device includes a substrate, a plurality of switching elements, a first sensing signal line, and a second sensing signal line. The substrate has a peripheral area. The plurality of switching elements is disposed on the substrate and is disposed in the peripheral area. The first sensing signal line is disposed on the substrate and is electrically connected to a first number of the plurality of switching elements. The second sensing signal line is disposed on the substrate and is electrically connected to a second number of the plurality of switching elements. Wherein, the plurality of switching elements is electrically connected to a common signal line, and the first number is different from the second number.

### CROSS REFERENCE TO RELATED APPLICATIONS

This application claims priority of China Patent Application No. CN 202310823958.X, filed on Jul. 6, 2023, the entirety of which is incorporated by reference herein.

### TECHNICAL FIELD

Some embodiments of the present disclosure relate to electronic devices, and, in particular, to electronic devices that include improved switching elements.

### BACKGROUND

Electronic products including chips, such as displays, smartphones, tablets, notebook computers, and televisions, have become indispensable necessities in modern society. With the booming development of this type of electronic products, consumers have high expectations of the quality, functionality, or price of these electronic products.

Electronic products often provide sensing functions through the use of sensing electrodes. However, as the complexity of electronic products increases, sensing electrodes may cause problems such as mura defects. Therefore, these electronic products do not meet consumer expectations in all respects, and there are still some problems to be solved in electronic products. The development of improved electronic devices remains one of the current goals.

### SUMMARY

In some embodiments, an electronic device is provided. The electronic device includes a substrate, a plurality of switching elements, a first sensing signal line, and a second sensing signal line. The substrate has a peripheral area. The plurality of switching elements is disposed on the substrate and is disposed in the peripheral area. The first sensing signal line is disposed on the substrate and is electrically connected to a first number of the plurality of switching elements. The second sensing signal line is disposed on the substrate and is electrically connected to a second number of the plurality of switching elements. Wherein, the plurality of switching elements is electrically connected to a common signal line, and the first number is different from the second number.

In some embodiments, an electronic device is provided. The electronic device includes a substrate, a first switching element and a second switching element, a first sensing signal line, and a second sensing signal line. The substrate has a peripheral area. The first switching element and the second switching element are disposed on the substrate and are disposed in the peripheral area. The first sensing signal line is disposed on the substrate and is electrically connected to the first switching element. The second sensing signal line is disposed on the substrate and is electrically connected to the second switching element. Wherein, a channel area of the first switching element has a first channel width along a direction, a channel area of the second switching element has a second channel width along the direction, and the first channel width is different from the second channel width.

The electronic device of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 shows an equivalent circuit diagram of an electronic device according to some embodiments of the present disclosure.

FIG. 2 shows a schematic layout diagram of an electronic device according to some embodiments of the present disclosure.

FIG. 3 shows a schematic top view of an electronic device according to some embodiments of the disclosure.

FIG. 4 shows a schematic top view of an electronic device according to some embodiments of the disclosure.

### DETAILED DESCRIPTION

Electronic devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific elements. A person of ordinary skills in the art should be understood that electronic device manufacturers may refer to the same element by different terms. The present disclosure does not intend to distinguish between elements that have the same function but with different terms. In the following description and claims, terms such as “including”, “comprising”, and “having” are open-ended words, so they should be interpreted as meaning “including but not limited to . . . ”. Therefore, when the terms “including”, “comprising”, and/or “having” is used in the description of the present disclosure, it designates the presence of corresponding features, regions, steps, operations, and/or elements, but does not exclude the presence of one or more corresponding features, regions, steps, operations, and/or elements.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 and the Y-axis direction is the second direction D2. In some embodiments, the schematic top views described herein are schematic views of the XY plane.

It should be understood that, according to the embodiments of the present disclosure, a depth, a thickness, a width, or a height of each element, and a spacing or a distance between elements may be measured by using an optical microscope (OM), a scanning electron microscope (SEM), a film thickness profiler (α-step), ellipsometer, or other suitable methods. In detail, according to some embodiments, a cross-sectional structure image including an element to be measured may be obtained by using the scanning electron microscope, and then the depth, the thickness, the width, or the height of the element, and the spacing or the distance between the element and another element may be measured.

In some embodiments, the electronic device of the present disclosure may include a display module, a back light module, an antenna module, a sensing module, or a titling module, but the present disclosure is not limited thereto. The electronic device may be a foldable or flexible electronic device. The display module may be a non-self-luminous display module or a self-luminous display module. The antenna module may be a liquid-crystal antenna module or a non-liquid-crystal antenna module. The sensing device may be a sensing module for sensing capacitance, light, heat, or ultrasonic waves, but the present disclosure is not limited thereto. The electronic elements may include passive elements and active elements, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs), or quantum dot light-emitting diodes (quantum dot LED), but the present disclosure is not limited thereto. The titling module may be, for example, a display titling module or an antenna titling module, but the present disclosure is not limited thereto.

In addition, the shape of the electronic device may be rectangular, circular, polygonal, a shape with curved edges, or another suitable shape. The electronic device may have a peripheral system, such as a processing system, a driving system, a controlling system, a light source system, a shelf system, or the like to support the display module or the titling module.

It should be understood that, for clarity of explanation, some elements of the electronic device may be omitted in the drawings, and some elements are schematically illustrated. In some embodiments, additional elements may be added to the electronic device described below. In other embodiments, some elements of the electronic device described below may be replaced or omitted. It should be understood that, in some embodiments, additional operational steps may be provided before, during, and/or after the forming method of an electronic device. In some embodiments, some of the described operational steps may be replaced or omitted, and the described order of some of the operational steps is interchangeable. In some embodiments, the electronic device may be a touch in display (TID) device, but the present disclosure is not limited thereto.

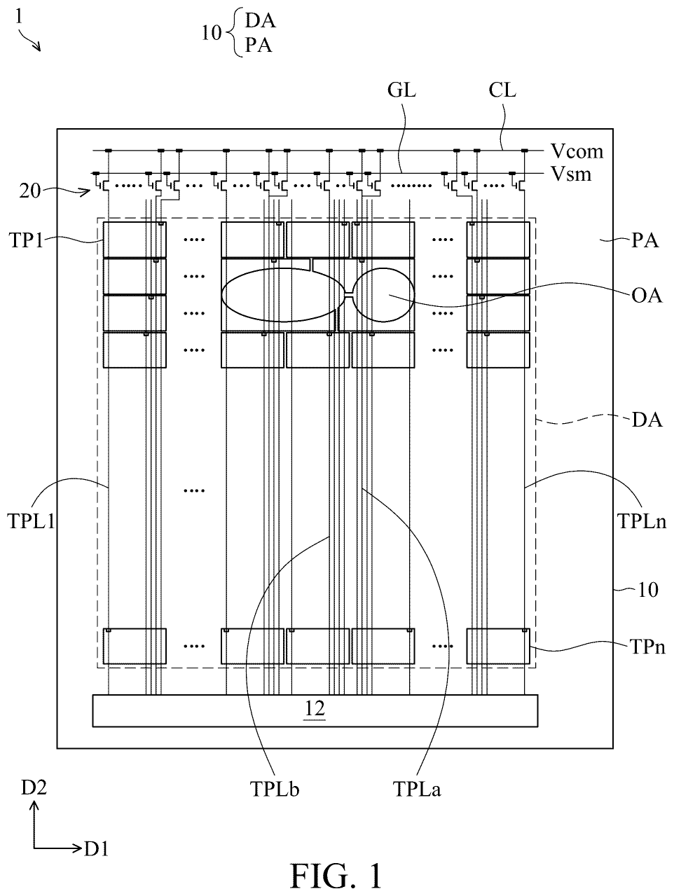

Referring to FIG. 1, it shows an equivalent circuit diagram of an electronic device 1 according to some embodiments of the present disclosure. In some embodiments, as shown in FIG. 1, the electronic device 1 may include a substrate 10, elements disposed on the substrate 10, and films (or layers) covering the substrate 10. In some embodiments, the electronic device 1 may include switching elements 20, sensing electrodes TP1 to TPn, sensing signal lines TPL1 to TPLn, a gate line GL, and a common signal line CL, but the present disclosure is not limited thereto.

In some embodiments, the substrate 10 may include a flexible substrate, a folded substrate, a rigid substrate, or a combination thereof, but the present disclosure is not limited thereto. In some embodiments, the substrate 10 may include wafer, glass, quartz, sapphire, ceramic, polyimide (PI), polycarbonate (PC), polyethylene terephthalate (PET), polypropylene (PP), other suitable materials, or a combination thereof, but the present disclosure is not limited thereto. In some embodiments, the substrate 10 may be a single-layer or multi-layer structure. In some embodiments, the substrate 10 may include a light-transmissive substrate, a semi-transparent substrate, or an opaque substrate.

In some embodiments, the substrate 10 may have a peripheral area PA and a display area DA adjacent to the peripheral area PA. In some embodiments, the display area DA may display images. For example, display pixels (not shown) may be disposed in the display area DA. In some embodiments, the peripheral area PA may be closer to the edge of the substrate 10 than the display area DA. In some embodiments, the peripheral area PA may surround at least one side of the display area DA. In some embodiments, the peripheral area PA may expose at least one side of the display area DA. In other embodiments, the peripheral area PA does not expose any sides of the display area DA. In some embodiments, as shown in FIG. 1, the display area DA may have a rectangular shape, but the present disclosure is not limited thereto. For example, the display area DA may have a circular shape, an elliptical shape, a polygonal shape, other suitable shapes, or a combination thereof. For example, the display area DA may include rounded corners, chamfers, arc edges, or a combination thereof.

In some embodiments, as shown in FIG. 1, the display area DA may include opening areas OA. Therefore, during subsequent processes, an optical sensing module, a communication module, other suitable modules, or a combination thereof may be disposed in the opening area OA. For example, the optical sensing module may include a photography module, a video module, the like, or a combination thereof, but the present disclosure is not limited thereto. For example, the communication module may include an earpiece module, a loudspeaker module, the like, or a combination thereof, but the present disclosure is not limited thereto.

In some embodiments, as shown in FIG. 1, a plurality of switching elements 20 may be disposed on the substrate 10 and disposed in the peripheral area PA of the substrate 10. In some embodiments, the plurality of switching elements 20 may include transistors. For example, the transistors may include a switching transistor. In some embodiments, the plurality of switching elements 20 may include two transistors connected in parallel. In some embodiments, the plurality of switching elements 20 may include, for example, metal oxide thin film transistors, amorphous silicon (a-Si) thin film transistors, or polycrystalline silicon (for example, low-temp polysilicon (LTPS)) thin film transistor, or a combination of the foregoing, but the present disclosure is not limited thereto. The metal oxide may include indium gallium zinc oxide (IGZO), indium zinc oxide (IZO), indium gallium oxide (IGO), indium gallium zinc tin oxide (IGZTO), other suitable materials, or a combination of the foregoing, but the present disclosure is not limited thereto.

In some embodiments, as shown in FIG. 1, a plurality of sensing electrodes TP1 to TPn may be disposed on the substrate 10 and disposed in the display area DA of the substrate 10 to provide the sensing function of the display area DA. Wherein “n” may be a positive integer. For example, the value of “n” may be adjusted according to parameters such as the sizes of the substrate 10 and the sensing electrodes TP1 to TPn. In some embodiments, the sensing electrodes TP1 to TPn may be arranged in an array in the display area DA of the substrate 10. In some embodiments, the sensing electrodes TP1 to TPn are not disposed in the peripheral area PA. In some embodiments, the sensing electrodes TP1 to TPn are not disposed in the opening area OA of the display area DA, in order to reduce the probability of interfering with other modules disposed in the opening area OA. In some embodiments, the sensing electrodes TP1 to TPn may serve as common electrodes, but the present disclosure is not limited thereto. In other embodiments, the electronic device 1 may further include other underlying electrodes electrically connected to the sensing electrodes TP1 to TPn.

In some embodiments, the sensing electrodes TP1 to TPn may have shapes corresponding to the display area DA. In some embodiments, the sensing electrodes TP1 to TPn may have a rectangular shape, but the present disclosure is not limited thereto. For example, the sensing electrodes TP1 to TPn may have a circular shape, an elliptical shape, a polygonal shape, other suitable shapes, or a combination thereof. For example, the sensing electrodes TP1 to TPn may include rounded corners, chamfers, arc edges, or a combination thereof. In some embodiments, a sensing electrode close to or adjacent to the opening area OA among the sensing electrodes TP1 to TPn may have a shape corresponding to the opening area OA. In some embodiments, as shown in FIG. 1, the opening area OA may be elliptical, and the sensing electrodes adjacent to the opening areas OA may be rectangular with arc edges, and the arc edges may correspond to the elliptical shape of the opening area OA.

In some embodiments, the sensing electrodes TP1 to TPn may include conductive materials. The conductive material may include metallic conductive material, transparent conductive material, or a combination thereof. For example, the metallic conductive material may include copper (Cu), aluminum (Al), molybdenum (Mo), silver (Ag), tin (Sn), tungsten (W), gold (Au), chromium (Cr), nickel (Ni), platinum (Pt), other suitable metals, alloys thereof, the like, or a combination thereof, but the present disclosure is not limited thereto. For example, the transparent conductive material may include transparent conductive oxide (TCO), such as indium tin oxide (ITO), tin oxide (SnO), zinc oxide (ZnO), indium zinc oxide (IZO), indium gallium zinc oxide (IGZO), indium tin zinc oxide (ITZO), antimony tin oxide (ATO), antimony zinc oxide (AZO), the like, or a combination thereof, but the present disclosure is not limited thereto. In some embodiments, the sensing electrodes TP1 to TPn may include indium tin oxide. In some embodiments, the sensing electrodes TP1 to TPn may be formed by, for example, chemical vapor deposition, sputtering, resistance heating evaporation, electron beam evaporation, physical vapor deposition, other suitable deposition processes, or a combination thereof, but the present disclosure is not limited thereto.

In some embodiments, as shown in FIG. 1, a plurality of sensing signal lines TPL1 to TPLn may be disposed on the substrate 10. In some embodiments, each of the sensing signal lines TPL1 to TPLn may be electrically connected to each of the sensing electrodes TP1 to TPn, respectively. In some embodiments, the plurality of sensing signal lines TPL1 to TPLn may be electrically connected to the plurality of switching elements 20. In some embodiments, the sensing signal lines TPL1 to TPLn may be spaced apart along the first direction D1, and the sensing signal lines TPL1 to TPLn may extend along the second direction D2. In some embodiments, the materials and formation methods of the sensing signal lines TPL1 to TPLn may be the same as or different from the materials and formation methods of the sensing electrodes TP1 to TPn. It should be understood that, although some of (or a portion of) the sensing signal lines TPL1 to TPLn in FIG. 1 are disposed in the opening area OA, these sensing signal lines TPL1 to TPLn may be disposed along the edge of the opening area OA, instead. In other words, the sensing signal lines TPL1 to TPLn may not overlap with the opening area OA.

In some embodiments, as shown in FIG. 1, the gate line GL may be disposed on the substrate 10, and the extending direction of the gate line GL is the first direction D1. In some embodiments, the gate line GL is electrically connected to the gates of the plurality of switching elements 20, so that the gate line GL provides the switching voltage Vsw to control the turning on or off of the plurality of switching elements 20. In some embodiments, the material and formation method of the gate line GL may be the same as or different from the materials and formation method of the sensing signal lines TPL1 to TPLn.

In some embodiments, as shown in FIG. 1, a common signal line CL may be disposed on the substrate 10, and the extending direction of the common signal line CL is the first direction D1. In some embodiments, the gate line GL and the common signal line CL may be substantially (or roughly) parallel with each other. In some embodiments, the common signal line CL may be electrically connected to the plurality of switching elements 20 to provide a common voltage Vcom through the common signal line CL. In some embodiments, the material and formation method of the common signal line CL may be the same as or different from the materials and formation method of the sensing signal lines TPL1 to TPLn.

In some embodiments, the electronic device 1 may further include an integrated circuit (IC) 12 to receive signals from the sensing electrodes TP1 to TPn. In some embodiments, the integrated circuit 12 may be disposed on the peripheral area PA of the substrate 10. In some embodiments, the integrated circuit 12 may be electrically connected to the plurality of switching elements 20 through the plurality of sensing signal lines TPL1 to TPLn. In some embodiments, the common signal line CL may be electrically connected to one of the source electrode and the drain electrode of the switching element 20, and the integrated circuit 12 may be electrically connected to the other of the source electrode and the drain electrode of the switching elements 20.

In the following, the same or similar reference numerals represent the same or similar elements, and for convenience of explanation, the repeated description will be omitted.

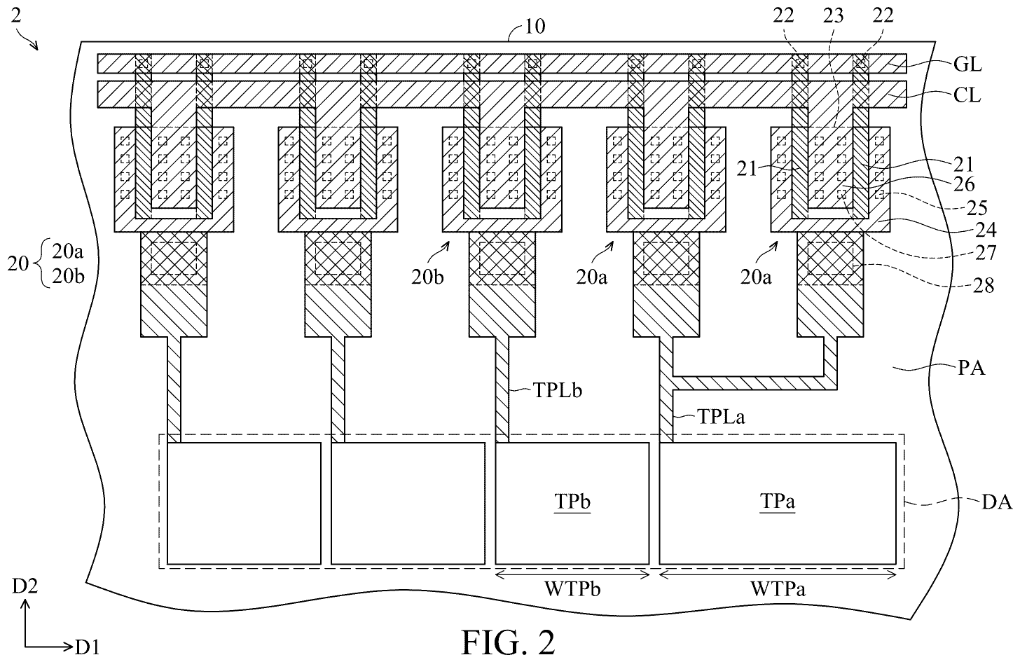

Referring to FIG. 2, it shows a schematic layout diagram of an electronic device 2 according to some embodiments of the present disclosure. In some embodiments, as shown in FIG. 2, any two sensing signal lines of the plurality of sensing signal lines TPL1 to TPLn are used as examples for explanation. In the following, the any two sensing signal lines are respectively referred to as the first sensing signal line TPLa and the second sensing signal line TPLb. In some embodiments, no other sensing signal line is provided between the first sensing signal line TPLa and the second sensing signal line TPLb. In other embodiments, another sensing signal lines is provided between the first sensing signal line TPLa and the second sensing signal line TPLb.

Hereinafter, the sensing electrodes connected to the first sensing signal line TPLa and the second sensing signal line TPLb respectively are referred to as the first sensing electrode TPa and the second sensing electrode TPb. In some embodiments, the first sensing signal line TPLa is electrically connected to the switching element 20a, and the first sensing signal line TPLa is electrically connected to the first sensing electrode TPa. In some embodiments, the second sensing signal line TPLb is electrically connected to the switching element 20b, and the second sensing signal line TPLb is electrically connected to the second sensing electrode TPb. In some embodiments, as shown in FIG. 2, the plurality of switching elements 20 may include a first number (or quantity or amount) of the switching elements 20a and a second number (or quantity or amount) of the switching elements 20b. In some embodiments, the switching elements 20a connected to the first sensing signal line TPLa are connected in parallel. In other embodiments, the switching elements 20b connected to the second sensing signal line TPLb are connected in parallel.

In some embodiments, as shown in FIG. 2, the switching element 20a may include a gate electrode 21, a semiconductor layer 23, a source electrode 24, and a drain electrode 26. In some embodiments, the gate electrode 21, the source electrode 24, and the drain electrode 26 may include conductive materials. In some embodiments, the semiconductor layer 23 may include semiconductor material.

In some embodiments, the gate electrode 21 may be disposed on the substrate 10. In some embodiments, the gate electrode 21 may be electrically connected to the gate line GL through the gate via 22. In some embodiments, as shown in FIG. 2, a pair of gate electrodes 21 may be provided to reduce the size of the switching element 20a, but the present disclosure is not limited thereto. In other embodiments, one switching element 20a may have one gate electrode 21. In some embodiments, the semiconductor layer 23 may be disposed on the gate electrode 21. In some embodiments, the source electrode 24 and the drain electrode 26 may be disposed on the semiconductor layer 23. In some embodiments, the source electrode 24 may be electrically connected to the semiconductor layer 23 through the source via 25, and the drain electrode 26 may be electrically connected to the semiconductor layer 23 through the drain via 27. In some embodiments, source electrode 24 and drain electrode 26 may be used interchangeably with each other. In some embodiments, the source electrode 24 may be U-shaped, but the present disclosure is not limited thereto. In some embodiments, the drain electrode 26 may be electrically connected to the common signal line CL. In some embodiments, the first sensing signal line TPLa may be disposed on the source electrode 24. In some embodiments, the source electrode 24 may be electrically connected to the first sensing signal line TPLa through the source via 28, so that the source electrode 24 may be connected to another layer through the source conductive hole 28.

In some embodiments, the gate electrode 21 may be the first metal layer (a M1 layer) of the electronic device 2, and the source electrode 24, the drain electrode 26, the gate line GL, and the common signal line CL may be the second metal layer (a M2 layer) of the electronic device 2, and the first sensing signal line TPLa may be the third metal layer (a M3 layer) of the electronic device 2. In some embodiments, an area of the semiconductor layer 23 between the source electrode 24 and the drain electrode 26 and corresponding to the gate electrode 21 may serve as a channel area of the switching element 20a. In some embodiments, the switching element 20a and the switching element 20b may be substantially the same switching element.

In some embodiments, as shown in FIG. 2, the first sensing signal line TPLa is electrically connected to a first number of switching elements 20, and the second sensing signal line TPLb is connected to a second number of switching elements 20, and the first number and the second number are different. Since the first number and the second number are different, the recovery capabilities of the common voltage Vcom of the sensing electrodes electrically respectively connected to the first number of switching elements 20 and the second number of switching elements 20 may be adjusted. Thus, the present disclosure is applicable to electronic devices including sensing electrodes with different areas or shapes.

For example, as shown in FIGS. 1 and 2, in order to comply with the design rules of the electronic device 1 and/or 2, the area or shape of the sensing electrode adjacent to the opening area OA is different from that of the sensing electrode away from the opening area OA. As the result, resistances of the sensing signal lines connected with different sensing electrodes are different. During the operation of the electronic device, the level of the common voltage Vcom will shift due to the capacitive coupling effect. Therefore, the integrated circuit 12 controls the switching element to recovery the level of the common voltage Vcom. When the resistance of the sensing signal line is too high, the recovery speed of the level of the common voltage Vcom recovered by the switching element is slow. This results in brightness differences between different sensing electrodes, causing problems such as mura defects. Therefore, compared with making the first number and the second number the same, making the first number and the second number different can improve the recovery ability of the switching element corresponding to the specific sensing electrode, thereby reducing the brightness difference between the sensing electrodes, improving the brightness uniformity of the sensing electrode, and/or improving the luminous effect (or the light-emitting effect) of the electronic device.

In some embodiments, as shown in FIG. 2, the first number is 2 and the second number is 1. It should be noted that, the first number and the second number shown in FIG. 2 are only examples, but the present disclosure is not limited thereto. In some embodiments, the first number and the second number may be positive integers. For example, the first number may be 1, 2, 3, 4, 5, 10, or any value or any range of values between the aforementioned values, but the present disclosure is not limited thereto. For example, the second number may be 1, 2, 3, 4, 5, 10, or any value or any range of values between the aforementioned values, but the present disclosure is not limited thereto. In some embodiments, the first number may be greater or less than the second number.

In some embodiments, as shown in FIG. 2, the first sensing electrode TPa has a first electrode width WTPa along a direction, the second sensing electrode TPb has a second electrode width WTPb along the direction, and the first electrode width WTPa of the first sensing electrode TPa is different from the second electrode width WTPb of the second sensing electrode TPb. In some embodiments, the direction is the extending direction of the gate line GL, that is, the first direction D1. In some embodiments, a third electrode width of the first sensing electrode TPa along a direction perpendicular to the extending direction of the gate line GL (that is, the second direction D2) is the same as a fourth electrode width of the second sensing electrode TPb along the direction perpendicular to the extending direction of the gate line GL.

In some embodiments, as shown in FIG. 2, the first electrode width WTPa of the first sensing electrode TPa may be greater than the second electrode width WTPb of the second sensing electrode TPb, and the first number may be greater than the second number. Accordingly, when the first electrode width WTPa is greater than the second electrode width WTPb, the first number of switching elements electrically connected to the first sensing electrode TPa and the first sensing signal line TPLa is increased, so that the first number is greater than the second number. Thus, the brightness difference between the first sensing electrode TPa and the second sensing electrode TPb may be reduced, the brightness uniformity of the first sensing electrode TPa and the second sensing electrode TPb may be improved, and/or the luminous effect of the electronic device 2 may be improved.

In some embodiments, the ratio of the first electrode width WTPa to the second electrode width WTPb (the first electrode width WTPa/the second electrode width WTPb) may be greater than 1.2. For example, the ratio of the first electrode width WTPa to the second electrode width WTPb (the first electrode width WTPa/the second electrode width WTPb) may be 1.2, 1.21, 1.5, 1.6, 1.7, 1.8, 1.9, 2, 2.5, 3, 3.5, 4, or any value or any range of values between the aforementioned values, but the present disclosure is not limited thereto. In some embodiments, the first sensing electrode TPa may be closer to the opening area OA than the second sensing electrode TPb, so as to reduce the brightness difference between the sensing electrode closer to the opening area OA and the sensing electrode away from the opening area OA, improve the brightness uniformity, and/or improve the luminous effect of the electronic device 2. In some embodiments, the first sensing electrode TPa may have a shape corresponding to the opening area OA.

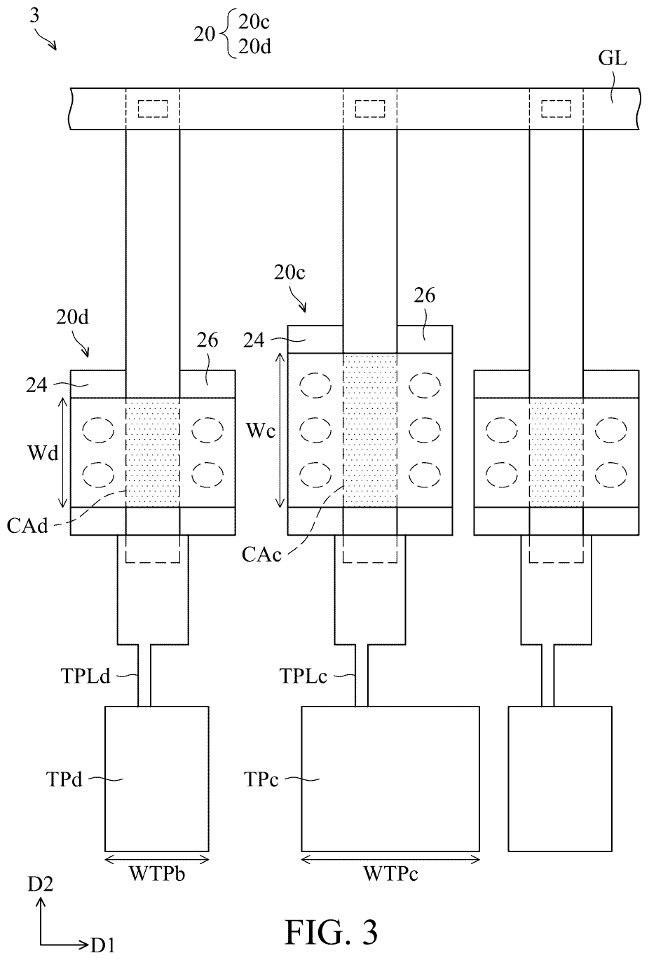

Referring to FIG. 3, it shows a schematic top view of an electronic device 3 according to some embodiments of the present disclosure. In some embodiments, as shown in FIG. 3, any two sensing signal lines of the plurality of sensing signal lines TPL1 to TPLn are used as examples for explanation. In the following, the any two sensing signal lines are respectively referred to as the third sensing signal line TPLc and the fourth sensing signal line TPLd. In some embodiments, no other sensing signal line is provided between the third sensing signal line TPLc and the fourth sensing signal line TPLd. In other embodiments, another sensing signal line is provided between the third sensing signal line TPLc and the fourth sensing signal line TPLd.

Hereinafter, the sensing electrodes connected to the third sensing signal line TPLc and the fourth sensing signal line TPLd respectively are referred to as the third sensing electrode TPc and the fourth sensing electrode TPd. In some embodiments, the third sensing signal line TPLc is electrically connected to the switching element 20c, and the third sensing signal line TPLc is electrically connected to the third sensing electrode TPc. In some embodiments, the fourth sensing signal line TPLd is electrically connected to the switching element 20d, and the fourth sensing signal line TPLd is electrically connected to the fourth sensing electrode TPd.

In some embodiments, as shown in FIG. 3, the size of the channel area CAc of the switching element 20c along a direction is different from the size of the channel area CAd of the switching element 20d along the direction. In some embodiments, the direction may be the extending direction of the gate line GL, that is, the first direction D1. In some embodiments, the direction may be a direction perpendicular to the extending direction of the gate line GL, that is, the second direction D2.

In some embodiments, as shown in FIG. 3, the third sensing electrode TPc is connected to the third sensing signal line TPLc, and has a third electrode Width WTPc along the extending direction of the gate line GL (the first direction D1). In some embodiments, the fourth sensing electrode TPd is connected to the fourth sensing signal line TPLd and has a fourth electrode width WTPd along the extending direction of the gate line GL. In some embodiments, the third electrode width WTPc is greater than the fourth electrode width WTPd. In some embodiments, the channel area CAc of the switching element 20c has a channel width Wc along a direction perpendicular to the extending direction of the gate line GL (the second direction D2), and the channel area CAd of the switching element 20d has a channel width Wd along the direction perpendicular to the extending direction of the gate line GL. In some embodiments, the channel width Wc is greater than the channel width Wd. Accordingly, since the channel width Wc of the switching element 20c is increased, the brightness difference between the third sensing electrode TPc and the fourth sensing electrode TPd may be reduced, the brightness uniformity between the third sensing electrode TPc and the fourth sensing electrode TPd may be improved, and/or the luminous effect of the electronic device 3 may be improved. In detail, by increasing the size of the channel area CAc along the extending direction of the source electrode 24 or the drain electrode 26, the recovery capability of the switching element corresponding to the specific sensing electrode is improved. In other words, the recovery capability of the switching element 20c is increased. Since the recovery capability of the switching element 20c may be greater than the switching element 20d, the third sensing electrode TPc may be closer to the opening area (shown in FIG. 1) than the fourth sensing electrode TPd.

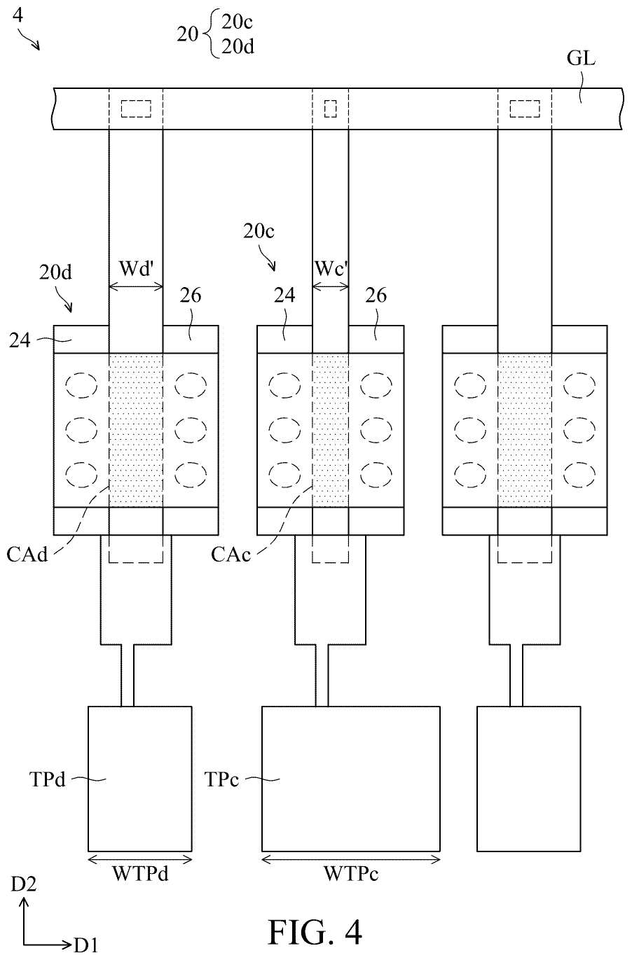

Referring to FIG. 4, it shows a schematic top view of an electronic device 4 according to some embodiments of the present disclosure. In some embodiments, as shown in FIG. 4, the third sensing electrode TPc is connected to the third sensing signal line TPLc and has the third electrode width WTPc along the extending direction of the gate line GL (the first direction D1). In some embodiments, the fourth sensing electrode TPd is connected to the fourth sensing signal line TPLd and has the fourth electrode width WTPd along the extending direction of the gate line GL. In some embodiments, the third electrode width WTPc is greater than the fourth electrode width WTPd. In some embodiments, the channel area CAc of the switching element 20c has a channel width Wc′ along the extending direction of the gate line GL (the first direction D1), and the channel area CAd of the switching element 20d has a channel width Wd′ along the extending direction of the gate line GL. In some embodiments, the channel width Wc′ is smaller than the channel width Wd′. Accordingly, since the channel width Wc′ of the switching element 20c is decreased, the brightness difference between the third sensing electrode TPc and the fourth sensing electrode TPd may be reduced, the brightness uniformity between the third sensing electrode TPc and the fourth sensing electrode TPd may be improved, and/or the luminous effect of the electronic device 4 may be improved. In detail, by reducing the size of the channel area CAc across the source electrode 24 to the drain electrode 26, the recovery capability of the switching element corresponding to the specific sensing electrode is improved. In other words, the recovery capability of the switching element 20c is increased. Since the recovery capability of the switching element 20c may be greater than the switching element 20d, the third sensing electrode TPc may be closer to the opening area (shown in FIG. 1) than the fourth sensing electrode TPd.

In other embodiments, the recovery capability of the switching element corresponding to the specific sensing electrode may be improved by increasing the size of the channel area of the switching element along the extending direction of the source electrode or the drain electrode, while reducing the size of the channel area of the switching element across the source electrode to the drain electrode. For example, the recovery capability of the switching element corresponding to the specific sensing electrode may be improved by increasing the ratio of the size along the extending direction of the source electrode (or the drain electrode) to the size across the source electrode to the drain electrode (the size along the extending direction of the source electrode (or the drain electrode)/the size across the source electrode to the drain electrode). In some embodiments, when the electrode width WTPc is greater than the electrode width WTPd, the channel width Wc is greater than the channel width Wd, and the channel width Wc′ is smaller than the channel width Wd′.

In some embodiments, the electronic devices 1, 2, 3, and/or 4 shown in FIGS. 1 to 4 can be used in any combination. In some embodiments, the switching elements 20, 20a, 20b, 20c, and/or 20d, the first to fourth sensing electrodes TPa to TPd, and/or the first to fourth sensing electrodes TPLa to TPLd shown in FIGS. 1 to 4 can be used in any combination.

In summary, according to embodiments of the present disclosure, an electronic device is provided. The electronic device can improve the recovery capability of the switching element corresponding to the specific sensing electrode by adjusting the number of switching elements connected to the sensing electrode and/or the size of the channel area. Therefore, the brightness difference between the sensing electrodes may be reduced, the brightness uniformity of the sensing electrodes may be improved, and/or the luminous effect of the electronic device may be improved.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a substrate having a peripheral area;
a plurality of switching elements disposed on the substrate and disposed in the peripheral area;
a first sensing signal line disposed on the substrate and electrically connected to a first number of the plurality of switching elements; and
a second sensing signal line disposed on the substrate and electrically connected to a second number of the plurality of switching elements,
wherein the plurality of switching elements is electrically connected to a common signal line, and the first number is different from the second number.

2. The electronic device as claimed in claim 1, wherein the switching elements connected to the first sensing signal line are connected in parallel.

3. The electronic device as claimed in claim 1, wherein the plurality of switching elements comprises transistors.

4. The electronic device as claimed in claim 3, wherein each of the transistors comprises a pair of gate electrodes.

5. The electronic device as claimed in claim 3, wherein each of the transistors comprises a source electrode and a drain electrode and either the source electrode or the drain electrode is U-shaped.

6. The electronic device as claimed in claim 3, wherein the transistors comprise two transistors connected in parallel.

7. The electronic device as claimed in claim 1, wherein the first sensing signal line is connected to a first sensing electrode, the second sensing signal line is connected to a second sensing electrode, and a first electrode width of the first sensing electrode along a direction is different from a second electrode width of the second sensing electrode along the direction.

8. The electronic device as claimed in claim 7, wherein the direction is an extending direction of a gate line.

9. The electronic device as claimed in claim 8, wherein the first electrode width is greater than the second electrode width, and the first number is greater than the second number.

10. The electronic device as claimed in claim 8, wherein a width of the first sensing electrode along a direction perpendicular to the extending direction of the gate line is the same as a width of the second sensing electrode along the direction perpendicular to the extending direction of the gate line.

11. The electronic device as claimed in claim 8, wherein a ratio of the first electrode width to the second electrode width is greater than 1.2.

12. The electronic device as claimed in claim 7, wherein the substrate has a display area adjacent to the peripheral area, the display area comprises an opening area, and the first sensing electrode is closer to the opening area than the second sensing electrode.

13. The electronic device as claimed in claim 12, wherein the first sensing electrode has a shape corresponding to the opening area.

14. The electronic device as claimed in claim 12, further comprising an optical sensing module, a communication module, or a combination thereof disposed in the opening area.

15. An electronic device, comprising:
a substrate having a peripheral area;
a first switching element and a second switching element disposed on the substrate and disposed in the peripheral area;
a first sensing signal line disposed on the substrate and electrically connected to the first switching element; and
a second sensing signal line disposed on the substrate and electrically connected to the second switching element,
wherein a channel area of the first switching element has a first channel width along a direction, a channel area of the second switching element has a second channel width along the direction, and the first channel width is different from the second channel width.

16. The electronic device as claimed in claim 15, further comprising:
a gate line disposed on the substrate and having an extending direction;
a first sensing electrode connected to the first sensing signal line and having a first electrode width along the extending direction; and
a second sensing electrode connected to the second sensing signal line and having a second electrode width along the extending direction, and the first electrode width is greater than the second electrode width,
wherein the channel area of the first switching element has the first channel width along a direction perpendicular to the extending direction, the channel area of the second switching element has the second channel width along the direction perpendicular to the extending direction, and the first channel width is greater than the second channel width.

17. The electronic device as claimed in claim 16, wherein the substrate has a display area adjacent to the peripheral area, the display area comprises an opening area, and the first sensing electrode is closer to the opening area than the second sensing electrode.

18. The electronic device as claimed in claim 16, wherein:
the channel area of the first switching element has a third channel width along the extending direction, the channel area of the second switching element has the fourth channel width along the extending direction, and the third channel width is smaller than the fourth channel width.

19. The electronic device as claimed in claim 15, further comprising:
a gate line disposed on the substrate and having an extending direction;
a first sensing electrode connected to the first sensing signal line and having a first electrode width along the extending direction; and
a second sensing electrode connected to the second sensing signal line and having a second electrode width along the extending direction, and the first electrode width is greater than the second electrode width,
wherein the channel area of the first switching element has the first channel width along the extending direction, the channel area of the second switching element has the second channel width along the extending direction, and the first channel width is smaller than the second channel width.

20. The electronic device as claimed in claim 19, wherein the substrate has a display area adjacent to the peripheral area, the display area comprises an opening area, and the first sensing electrode is closer to the opening area than the second sensing electrode.
